(19) United States
(12) Patent Application Publication
(10) Pub. No.: US 2025/0218835 A1
(43) Pub. Date: Jul. 3, 2025

(54) TOWER LIFT AND CONTROL METHOD THEREOF

(71) Applicant: SEMES CO., LTD., Chungcheongnam-do (KR)

(72) Inventor: Chong Whan LEE, Chungcheongnam-do (KR)

(21) Appl. No.: 18/983,327

(22) Filed: Dec. 16, 2024

(30) Foreign Application Priority Data
Dec. 27, 2023 (KR) 10-2023-0193423

(51) Int. Cl. H01L 21/677

(52) U.S. Cl. CPC H01L 21/67706; H01L 21/67709; H01L 21/67715; H01L 21/67736

(57) ABSTRACT

There is provided a tower lift capable of increasing the transport efficiency. The tower lift includes a frame unit including a first frame extending in a first direction, a second frame extending in a second direction perpendicular to the first direction, and a third frame extending in a third direction perpendicular to the first direction and the second direction, a horizontal driving unit installed on the first frame and the second frame, a vertical driving unit installed on the third frame, a mast unit vertically moving along the third frame by the vertical driving unit and horizontally moving along the first frame and the second frame by the horizontal driving unit; and a carrier fixed to the mast unit and moving together as the mast unit moves and carrying a container.

### CROSS-REFERENCE TO RELATED APPLICATION

This application claims priority from Korean Patent Application No. 10-2023-0193423 filed on Dec. 27, 2023 in the Korean Intellectual Property Office, and all the benefits accruing therefrom under 35 U.S.C. 119, the contents of which in its entirety are herein incorporated by reference.

### BACKGROUND

### Technical Field

The present disclosure relates to a tower lift and a control method thereof.

### Description of the Related Art

In general, a manufacturing line of a semiconductor or display manufacturing plant is composed of multiple layers, and each layer may be equipped with facilities for performing processes such as deposition, exposure, etching, ion implantation, and cleaning. Also, a semiconductor device or a display device may be manufactured by repeatedly performing a series of unit processes on a semiconductor wafer used as a semiconductor substrate or a glass substrate used as a display substrate. Meanwhile, material transport between each of the layers, i.e., transport of materials such as semiconductor wafers or glass substrates, may be performed by a tower lift installed vertically through each of the layers.

As semiconductor manufacturing lines become larger, a single structure of an ascending and descending passage has limitations in the transport speed and movement number of materials. Therefore, a tower lift that may accommodate the high-rise/multi-layer structure that follows the larger semiconductor manufacturing lines is required.

Aspects and features of embodiments of the present disclosure are to provide a tower lift capable of increasing the transport efficiency.

Another aspects and features of embodiments of the present disclosure are to provide a tower lift control method capable of increasing transport efficiency.

The technical problems of the present disclosure are not limited to the above-mentioned technical problems, and other technical problems not mentioned will be clearly understood by those skilled in the art from the description below.

According to some aspects of the disclosure, there is provided a tower lift comprising a frame unit including a first frame extending in a first direction, a second frame extending in a second direction perpendicular to the first direction, and a third frame extending in a third direction perpendicular to the first direction and the second direction, a horizontal driving unit installed on the first frame and the second frame, a vertical driving unit installed on the third frame, a mast unit vertically moving along the third frame by the vertical driving unit and horizontally moving along the first frame and the second frame by the horizontal driving unit; and a carrier fixed to the mast unit and moving together as the mast unit moves and carrying a container.

According to some aspects of the disclosure, there is provided a control method of tower lift comprising a frame unit including a first frame extending in a first direction, a second frame extending in a second direction perpendicular to the first direction, and a third frame extending in a third direction perpendicular to the first direction and the second direction, a horizontal driving unit installed on the first frame and the second frame, a vertical driving unit installed on the third frame, a mast unit moving along the frame unit, a tower lift is provided, which includes a carrier that is fixed to the mast unit and moves together with the mast unit as it moves, and a controller that controls the mast unit and the horizontal driving unit, and wherein the vertical driving unit vertically moves the mast unit in a magnetically levitated manner, wherein the controller controls, the mast unit to horizontally move the first frame and the second frame by the horizontal driving unit, and the mast unit to vertically move the third frame by the vertical driving unit.

According to some aspects of the disclosure, there is provided a tower lift comprising a frame unit including a first frame extending in a first direction, a second frame extending in a second direction perpendicular to the first direction, and a third frame extending in a third direction perpendicular to the first direction and the second direction, the frame unit including a front side and a rear side spaced apart in a direction opposite to the front side, a horizontal driving unit installed on the first frame and the second frame, a vertical driving unit installed on the third frame, a mast unit that moves vertically along the third frame in a magnetically levitated manner by the vertical driving unit and moves horizontally along the first frame and the second frame by the horizontal driving unit and a carrier that is fixed to the mast unit and moves together with the mast unit as it moves, and carries a container, wherein the frame unit includes a plurality of loading and unloading layers including a lowermost loading and unloading layer and an uppermost loading and unloading layer higher than the lowermost loading and unloading layer, wherein the vertical driving unit, vertically moves the mast unit from the lowermost loading and unloading layer to the uppermost loading and unloading layer at the front of the frame unit, and vertically moves the mast unit from the uppermost loading and unloading layer to the lowermost loading and unloading layer at the rear of the frame unit.

### BRIEF DESCRIPTION OF THE DRAWINGS

FIG. 1 is a drawing to illustrate a mast unit of a tower lift according to some embodiments of the present disclosure.

FIG. 2 is a drawing to illustrate a tower lift according to some embodiments of the present disclosure.

FIG. 3 is an enlarged drawing of a portion P of FIG. 2.

FIG. 4 is a front view of the frame unit of FIG. 2.

FIG. 5 is a side view of the frame unit of FIG. 2.

FIG. 6 is a plan view of the frame unit of FIG. 2.

FIG. 7 is a drawing to illustrate a tower lift according to some embodiments of the present disclosure.

FIGS. 8 to 12 are drawings to illustrate a tower lift control method according to some embodiments of the present disclosure.

FIGS. 13 to 17 are drawings to illustrate a tower lift control method according to some embodiments of the present disclosure.

FIGS. 18 to 21 are drawings to illustrate a tower lift control method according to some embodiments of the present disclosure.

FIGS. 22 and 23 are drawings to illustrate a tower lift control method according to some embodiments of the present disclosure.

### DETAILED DESCRIPTION

In this specification, although the terms “first,” “second,” “upper”, “lower”, and the like are used to describe various elements or components, these elements or components are not limited by these terms. These terms are only used to distinguish one element or component from another element or component. Therefore, the first element or component mentioned below may also be the second element or component within the technical concept of the present disclosure. Also, the lower elements or components mentioned below may also be upper elements or components within the technical concept of the present disclosure.

Hereinafter, embodiments of the present disclosure will be described in detail with reference to the attached drawings. Identical components in the drawings are designated by the same reference numerals, and redundant descriptions thereof will be omitted.

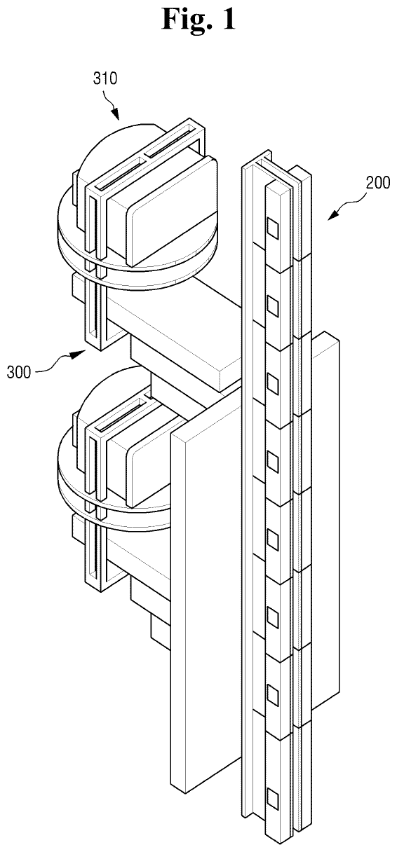

FIG. 1 is a drawing to illustrate a mast unit of a tower lift according to some embodiments of the present disclosure.

Referring to FIG. 1, a tower lift according to some embodiments of the present disclosure may include a mast unit 200.

The mast unit 200 may extend in a vertical direction. The mast unit 200 illustrated in FIG. 1 has a rectangular parallelepiped shape but is not limited thereto. The mast unit 200 may include a plurality of fasteners and may be connected to one or more carriers 300.

The mast unit 200 may be driven in a ropeless manner.

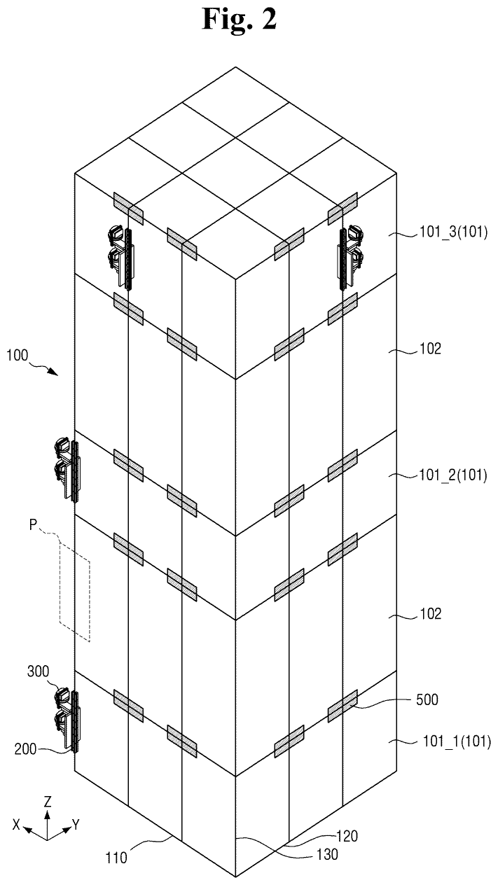

In some embodiments, the mast unit 200 may be moved along a frame unit (100 in FIG. 2) in a magnetically levitated manner. Although not shown, in some embodiments, the mast unit 200 may be moved by a linear motor. For example, a linear motor that provides a driving force for moving the mast unit 200 may be installed in the frame unit 100. Therefore, the tower lift according to some embodiments of the present disclosure may be capable of multi-carriage operation without constraints such as carriers and motors.

The tower lift according to some embodiments of the present disclosure may be operated through a plurality of mast units 200. For example, the mast unit 200 may be moved through the frame unit 100 described below. The mast unit 200 may be moved left or right through the frame unit 100. The mast unit 200 may be moved forward or backward through the frame unit 100. The mast unit 200 may be moved up or down through the frame unit 100.

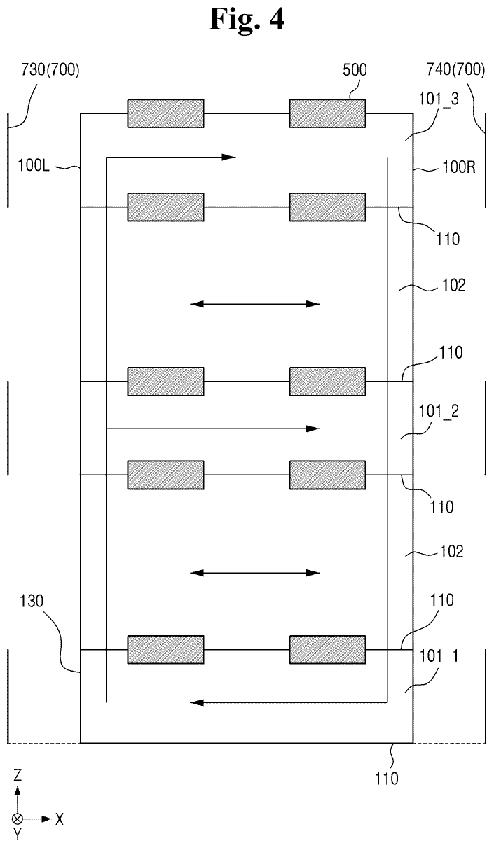

The mast unit 200 may include a carrier 300 that accommodates a container 310. The carrier 300 may load and unload the container 310 from a loading and unloading port (700 in FIG. 4) described later. The container 310 may be a FOUP in which a plurality of substrates are stored.

The carrier 300 may be integrally connected to the mast unit 200. Therefore, the carrier 300 may be moved integrally with the mast unit 200. The mast unit 200 including the carrier 300 moves in front of the loading and unloading port 700 so that the carrier 300 may load and unload the container 310. After the carrier 300 loads and unloads the container 310, the mast unit 200 may move to another position along the frame unit 100.

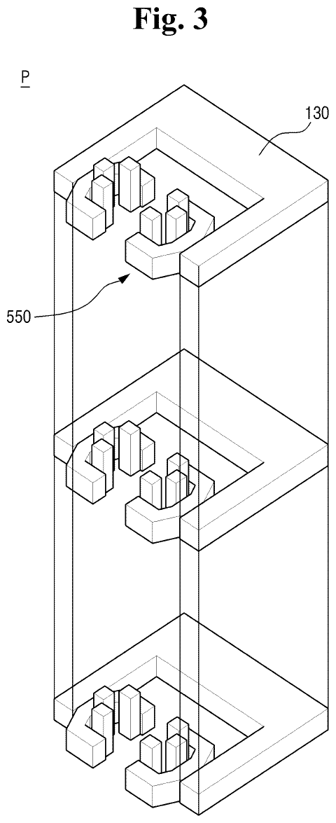

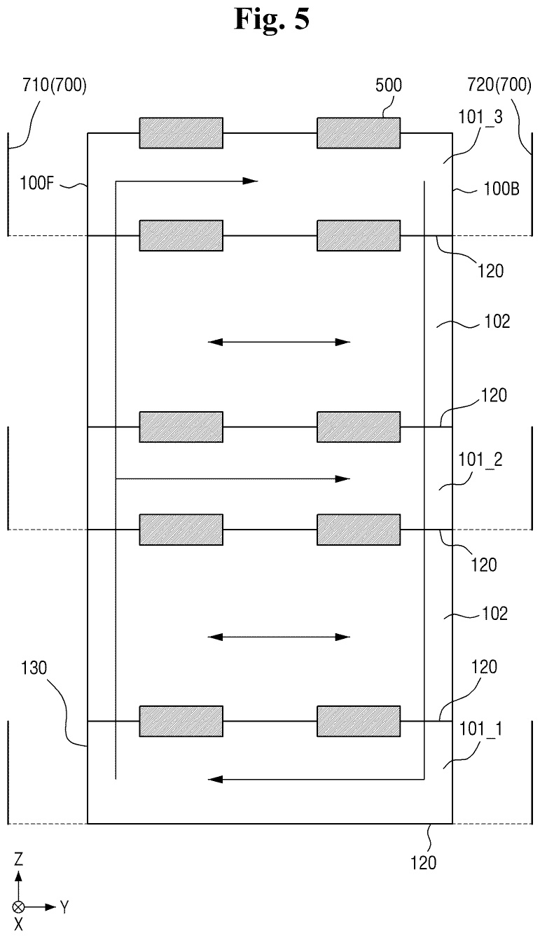

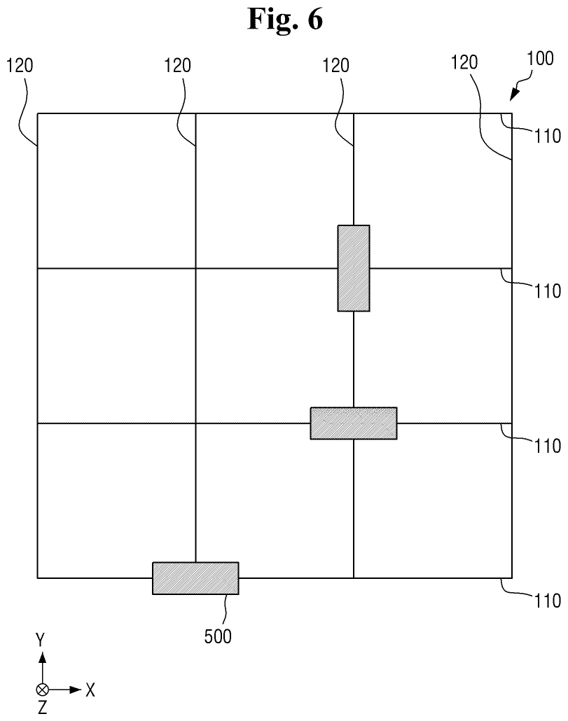

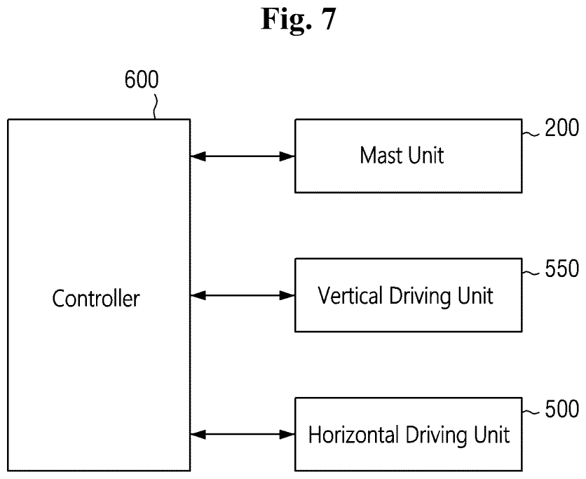

FIG. 2 is a drawing to illustrate a tower lift according to some embodiments of the present disclosure. FIG. 3 is an enlarged drawing of a portion P of FIG. 2. FIG. 4 is a front view of the frame unit of FIG. 2. FIG. 5 is a side view of the frame unit of FIG. 2. FIG. 6 is a plan view of the frame unit of FIG. 2. FIG. 7 is a drawing to illustrate a tower lift according to some embodiments of the present disclosure.

Referring to FIG. 2, a tower lift according to some embodiments of the present disclosure may include a frame unit 100, a mast unit 200, a vertical driving unit 550, and a horizontal driving unit 500.

The frame unit 100 may include a plurality of first frames 110 extending in a first direction X, a plurality of second frames 120 extending in a second direction Y, a plurality of third frames 130 extending in a third direction Z, a plurality of loading and unloading layers 101, and a branch passage 102.

In this specification, the first direction X, the second direction Y, and the third direction Z may intersect with each other. The first direction X, the second direction Y, and the third direction Z may be substantially vertical.

A plurality of first frames 110 may be installed on each layer of the frame unit 100. The mast unit 200 may be moved left or right through the first frame 110.

A plurality of second frames 120 may be installed on each layer of the frame unit 100. The mast unit 200 may be moved forward or backward through the second frame 120.

The third frame 130 may be a column of the frame unit 100. A plurality of third frames 130 may be installed by being connected to the first frame 110 and the second frame 120.

The mast unit 200 may be moved up and down through the third frame 130. Referring to FIG. 3, a plurality of vertical driving units 550 may be installed on the third frame 130. The vertical driving units 550 may move the mast unit 200 in a magnetic levitation manner. Each of the third frames 130 has a vertical driving unit 550 installed thereon to move the mast unit 200 up or down.

The vertical driving units 550 may move the mast unit 200 in one direction. For example, the vertical driving unit 550 may vertically move the mast unit 200 from a lowest loading and unloading layer 101_1 to a highest loading and unloading layer 101_3 at the front of the frame unit 100 (100F in FIG. 5) and may vertically move the mast unit 200 from the highest loading and unloading layer 101_3 to the lowest loading and unloading layer 101_1 at the rear of the frame unit 100 (100B in FIG. 5).

As another example, the vertical driving unit 550 may vertically move the mast unit 200 from the lowest loading and unloading layer 101_1 to the highest loading and unloading layer 101_3 on the left side (100L in FIG. 4) of the frame unit 100 and vertically move the mast unit 200 from the highest loading and unloading layer 101_3 to the lowest loading and unloading layer 101_1 on the right side (100R in FIG. 4) of the frame unit 100.

Referring again to FIG. 2, the plurality of loading and unloading layers 101 may include the lowest loading and unloading layer 101_1, a middle loading and unloading layer 101_2, and the highest loading and unloading layer 101_3. In FIG. 3, the plurality of loading and unloading layers 101 are illustrated as three but are not limited thereto. The number of the plurality of loading and unloading layers 101 may be increased as much as necessary depending on the size of the semiconductor fab.

The plurality of loading and unloading layers 101 may provide the loading and unloading for the container 310. The loading and unloading port 700 may be located in front of the front 100F, the back 100B, the left side 100L, or the right side 100R of the plurality of loading and unloading layers 101. Each mast unit 200 may load and unload a container 310 through a carrier 300 from one loading and unloading layer 101 and then move to another loading and unloading layer 101 to load and unload the container 310. For example, one mast unit 200 may load and unload a container 310 from the lowest loading and unloading layer 101_1, then move to the middle loading and unloading layer 101_2 or the highest loading and unloading layer 101_3 and then load and unload the container 310.

The mast unit 200 may move up and down, left and right, and front and back in the plurality of loading and unloading layers 101. Accordingly, loading and unloading of the container 310 may be performed from the back, front, and side in the plurality of loading and unloading layers 101.

The branch passage 102 may exist between the plurality of loading and unloading layers 101. For example, when the plurality of loading and unloading layers 101 include a first loading and unloading layer 101 and a second loading and unloading layer 101, the branch passage 102 may exist between the first loading and unloading layer 101 and the second loading and unloading layer 101. In FIG. 3, two branch passageways 102 are illustrated but are not limited thereto. As the number of loading and unloading layers 101 increases, the number of branch passages 102 may increase.

The mast unit 200 may be moved through the branch passage 102. The loading and unloading of the container 310 may not occur in the branch passage 102. The branch passage 102 may be included in the tower lift according to some embodiments of the present disclosure, thereby providing an additional movement path for the mast unit 200.

In some embodiments, the first mast unit 200 of the mast units 200 may be moved along the loading and unloading layer 101, and the second mast unit 200 may be moved along the branch passage 102. Since the mast unit 200 may be moved along the loading and unloading layer 101 and the branch passage 102, the movement path may be shortened.

The mast unit 200 may be moved along the frame unit 100. For example, the mast unit 200 may be moved left or right along the first frame 110 of the frame unit 100. The mast unit 200 may be moved forward or backward along the second frame 120 of the frame unit 100. The mast unit 200 may be moved up or down along the third frame 130 of the frame unit 100.

The mast unit 200 may be moved along the plurality of loading and unloading layers 101 and the branch passage 102. The mast unit 200 may have an optimized movement path because the loading and unloading layers 101 and the branch passage 102 exist. In the case where the first mast unit 200 among the mast units 200 exists in the plurality of loading and unloading layers 101 and may not be moved to the loading and unloading layer 101, the second mast unit 200 may be moved along the branch passage 102. That is, if the first mast unit 200 exists in the plurality of loading and unloading layers 101 and the second mast unit 200 is waiting, the second mast unit 200 may be moved through the branch passage 102.

For example, referring to FIG. 5, in a situation where the second mast unit 200 need to load and unload a container 310 from the front loading and unloading port 710 of the lowest loading and unloading layer 101_1 and move to the rear loading and unloading port 720 of the intermediate loading and unloading layer 101_2, if the first mast unit 200 is present in the intermediate loading and unloading layer 101_2 and may not move to the intermediate loading and unloading layer 101_2, it may move along the branch passage 102 existing between the intermediate loading and unloading layer 101_2 and the uppermost loading and unloading layer 101_3 and move to the rear loading and unloading port 720 of the intermediate loading and unloading layer 101_2.

In another example, when the second mast unit 200 is to load and unload a container 310 from the rear loading and unloading port 720 of the uppermost loading and unloading layer 101_3 and move to the front loading and unloading port 710 of the uppermost loading and unloading layer 101_3, and the first mast unit 200 is present in the uppermost loading and unloading layer 101_3 and may not move, it may move along the branch passage 102 between the uppermost loading and unloading layer 101_3 and the middle loading and unloading layer 101_2 and move to the front loading and unloading port 710 of the uppermost loading and unloading layer 101_3.

Referring again to FIG. 2, the horizontal driving unit 500 may be installed in the frame unit 100. For example, the horizontal driving unit 500 may be installed in the first frame 110 and the second frame 120 of the frame unit 100. A plurality of horizontal driving units 500 may be installed in the first frame 110 and the second frame 120.

The horizontal driving unit 500 may be detachably attached to the mast unit 200. The horizontal driving unit 500 may move the mast unit 200 left and right or forward and backward. The horizontal driving unit 500 may rotate the mast unit 200 through 360 degrees about the third direction Z as an axis. For example, when the mast unit 200 vertically moves the loading and unloading layer 101 or the branch passage 102 along the third frame 130, the horizontal driving unit 500 may be coupled with the mast unit 200. The mast unit 200 coupled with the horizontal driving unit 500 may be moved left and right or forward and backward.

The horizontal driving unit 500 may move the mast unit 200 to move in front of the loading and unloading port 700. For example, the horizontal driving unit 500 may move the mast unit 200 from the front loading and unloading port 710 to the rear loading and unloading port 720.

After the mast unit 200 loads and unloads from the front loading and unloading port 710, the horizontal driving unit 500 may rotate and move the mast unit 200 to be disposed in front of the rear loading and unloading port 720.

Referring to FIGS. 4 and 5, the mast unit 200 may circulate the frame unit 100 clockwise.

For example, in FIG. 4, the mast unit 200 in the left loading and unloading port 730 may be moved from the lowest loading and unloading layer 101_1 to the highest loading and unloading layer 101_3 along the third frame 130. Then, in the highest loading and unloading layer 101_3, the mast unit 200 may be moved from the left loading and unloading port 730 to the right loading and unloading port 740 along the first direction X by the horizontal driving unit 500. Next, in the right-side loading and unloading port 740, the mast unit 200 may be moved from the highest loading and unloading layer 101_3 to the lowest loading and unloading layer 101_1 along the third frame 130. Next, in the lowest loading and unloading layer 101_1, the mast unit 200 may be moved from the right-side loading and unloading port 740 to the left-side loading and unloading port 730 along the first direction X by the horizontal driving unit 500.

For example, in FIG. 5, in the front loading and unloading port 710, the mast unit 200 may be moved from the lowest loading and unloading layer 101_1 to the highest loading and unloading layer 101_3 along the third frame 130. Next, in the highest loading and unloading layer 101_3, the mast unit 200 may be moved from the front loading and unloading port 710 to the rear loading and unloading port 720 along the first direction X by the horizontal driving unit 500. Next, in the rear loading and unloading port 720, the mast unit 200 may be moved from the highest loading and unloading layer 101_3 to the lowermost loading and unloading layer 101_1 along the third frame 130. Next, in the lowermost loading and unloading layer 101_1, the mast unit 200 may be moved from the rear loading and unloading port 720 to the front loading and unloading port 710 by the horizontal driving unit 500.

The mast unit 200 may be moved in both directions in the branch passage 102. For example, the mast unit 200 may be moved left and right or forward and backward using the branch passage 102 existing between the lowest loading and unloading layer 101_1 and the middle loading and unloading layer 101_2 and between the middle loading and unloading layer 101_2 and the top loading and unloading layer 101_3.

In some embodiments, the direction in which the mast unit 200 moves in the lowest loading and unloading layer 101_1 and the branch passage 102 may be opposite to the direction in which it moves in the highest loading and unloading layer 101_3. Also, in some embodiments, the direction in which the mast unit 200 moves in the highest loading and unloading layer 101_3 and the branch passage 102 may be opposite to the direction in which it moves in the lowest loading and unloading layer 101_1.

Referring to FIG. 6, the horizontal driving unit 500 may move in the first direction X along the first frame 110. That is, the horizontal driving unit 500 may move left and right along the first frame 110.

The horizontal driving unit 500 may move in the second direction Y along the second frame 120. That is, the horizontal driving unit 500 may move back and forth along the second frame 120. Therefore, the horizontal driving unit 500 may be combined with the mast unit 200 to move the mast unit 200 left and right or back and forth.

Referring to FIG. 7, the tower lift according to some embodiments of the present disclosure may further include a controller 600.

The controller 600 may control the mast unit 200, the vertical driving unit 550, and the horizontal driving unit 500.

In some embodiments, the movement of the mast unit 200 may be controlled by the controller 600. The vertical driving unit 550 may be controlled by the controller 600 so that the mast unit 200 coupled with the vertical driving unit 550 may be controlled to move along the third frame 130.

The horizontal driving unit 500 may be controlled by the controller 600 so that the mast unit 200 may be moved along the loading and unloading layer 101 or the branch passage 102. The horizontal driving unit 500 may be controlled by the controller 600 so that the mast unit 200 coupled with the horizontal driving unit 500 may be controlled to move along the first frame 110 or the second frame 120.

The controller 600 controls the mast unit 200, the vertical driving unit 550, and the horizontal driving unit 500, so that the mast unit 200 may be controlled to circulate the plurality of loading and unloading layers 101 clockwise along the first frame 110 and the third frame 130. Further, the controller 600 controls the mast unit 200, the vertical driving unit 550, and the horizontal driving unit 500, so that the mast unit 200 may be controlled to circulate the plurality of loading and unloading layers 101 clockwise along the second frame 120 and the third frame 130.

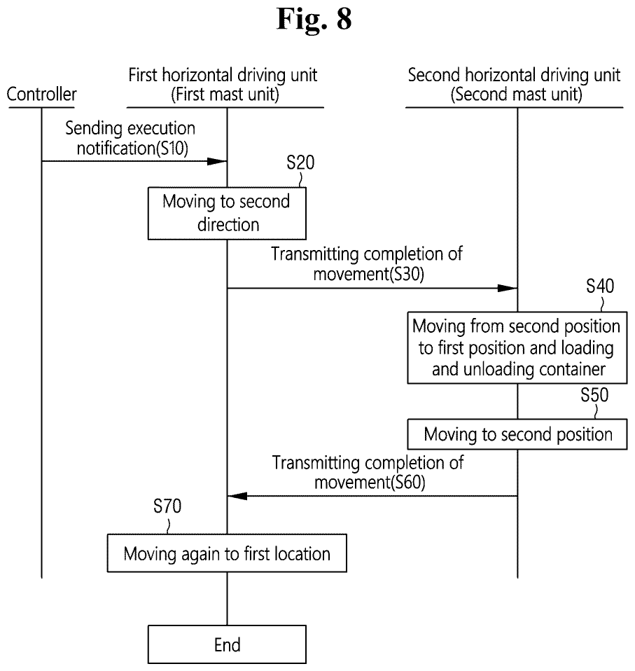

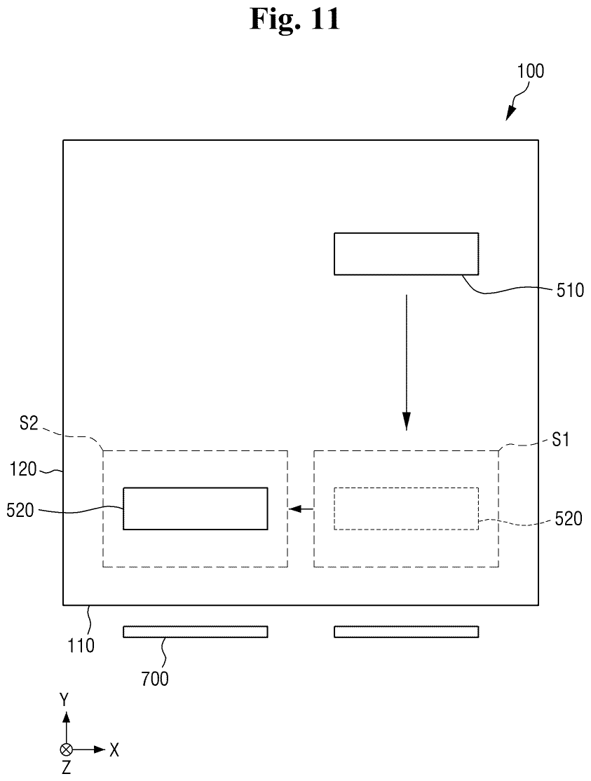

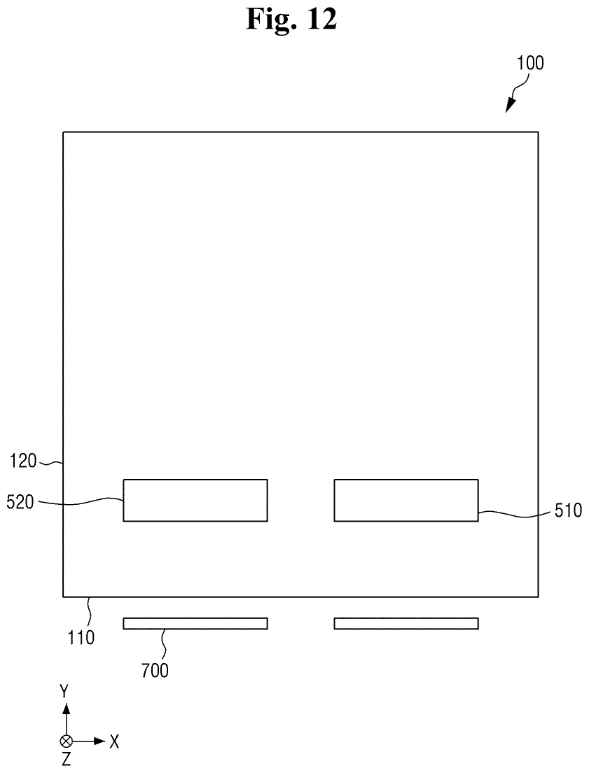

FIGS. 8 to 12 are drawings to illustrate a tower lift control method according to some embodiments of the present disclosure.

FIG. 8 is a flow chart illustrating an operation process of a mast unit 200 including a carrier 300 storing a container 310 for efficiently loading and unloading a container 310.

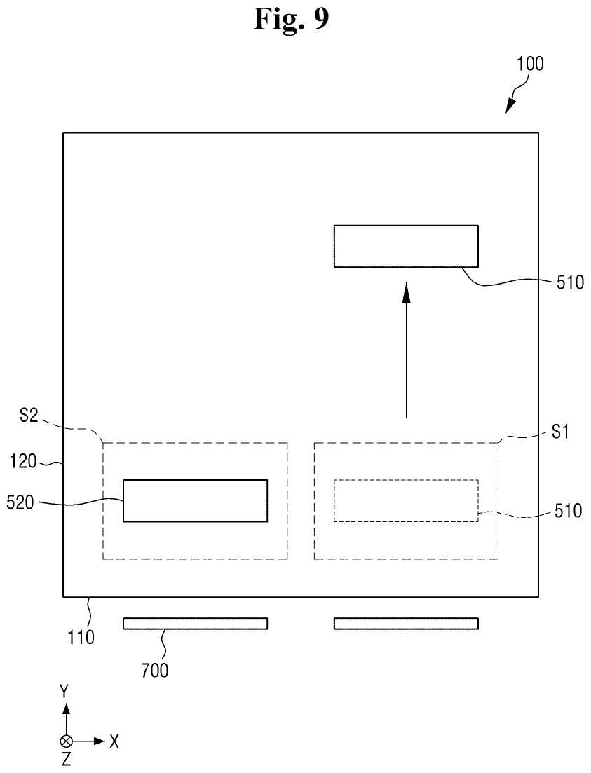

Referring to FIGS. 8 and 9, a first horizontal driving unit 510 coupled with a first mast unit 200 and a second horizontal driving unit 520 coupled with a second mast unit 200 may be disposed in a loading and unloading layer 101. The first horizontal driving unit 510 and the first mast unit 200 may be disposed at a first position S1. The first position S1 may be a position for loading and unloading a container 310. The second horizontal driving unit 520 and the second mast unit 200 may be located at a second position S2. The second position S2 may be spaced apart from the first position S1 in the first direction X. The first mast unit 200 located at the first position S1 may be in a state where the loading and unloading are completed.

When the controller 600 transmits an execution notification to the first horizontal driving unit 510 (S10), the first horizontal driving unit 510 moves in the second direction Y (S20). In this case, the first mast unit 200 coupled to the first horizontal driving unit 510 may move together in the second direction Y.

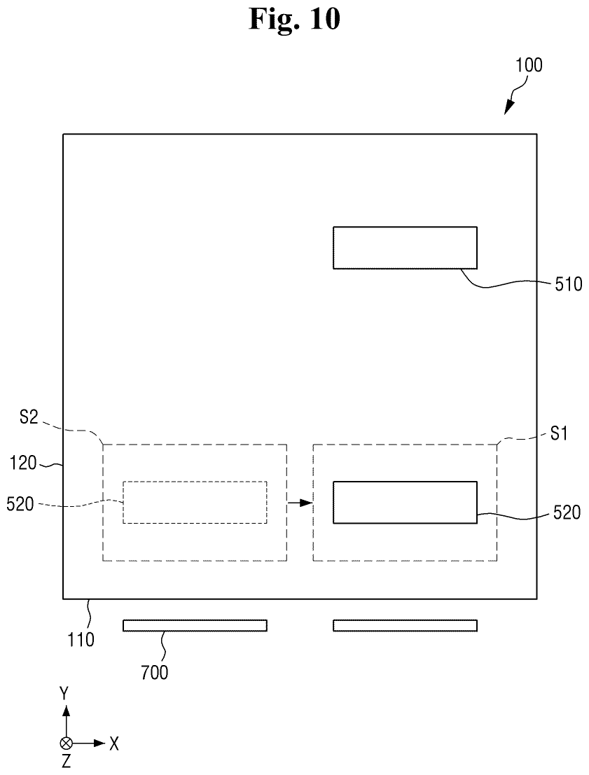

Referring to FIGS. 8 and 10, when the first horizontal driving unit 510 completes moving in the second direction Y, it transmits the completion of the movement to the second horizontal driving unit 520 (S30). When the movement completion signal is received, the second horizontal driving unit 520 moves from the second position S2 to the first position S1 and loads and unloads the container 310 contained in the carrier 300 connected to the second mast unit 200 (S40).

Referring to FIGS. 8, 11, and 12, the second horizontal driving unit 520 then moves to the second position S2 and transfers the movement completion signal to the first horizontal driving unit 510 (S50, S60). When the movement completion signal is received, the first horizontal driving unit 510 moves back to the first position S1 (S70).

Through the above-described operation process, the mast unit 200 may efficiently perform the loading and unloading process. When the first mast unit 200 has completed the loading and unloading, the second mast unit 200 may be moved from the second position S2 to the first position S1 for the loading and unloading. After the loading and unloading of the second mast unit 200 has been completed, the first mast unit 200 and the second mast unit 200 may be moved back to their original positions. In this way, the crowding phenomenon of the loading and unloading process may be avoided when a plurality of mast units 200 are present in the loading and unloading layer 101.

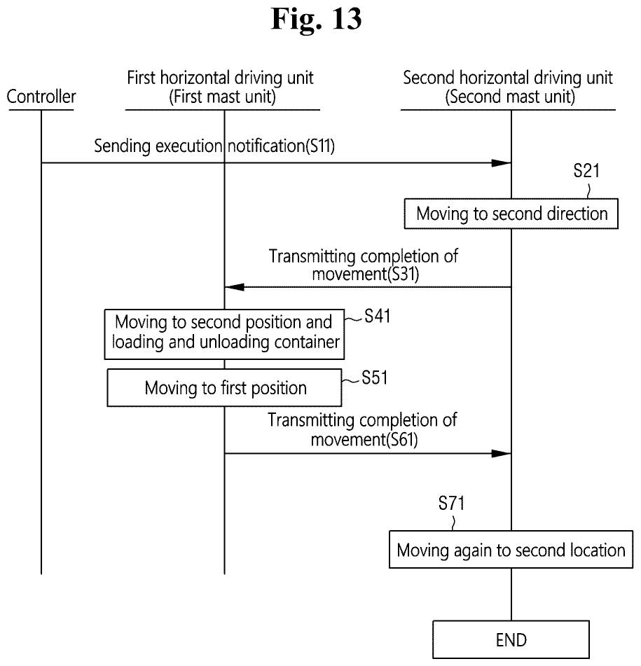

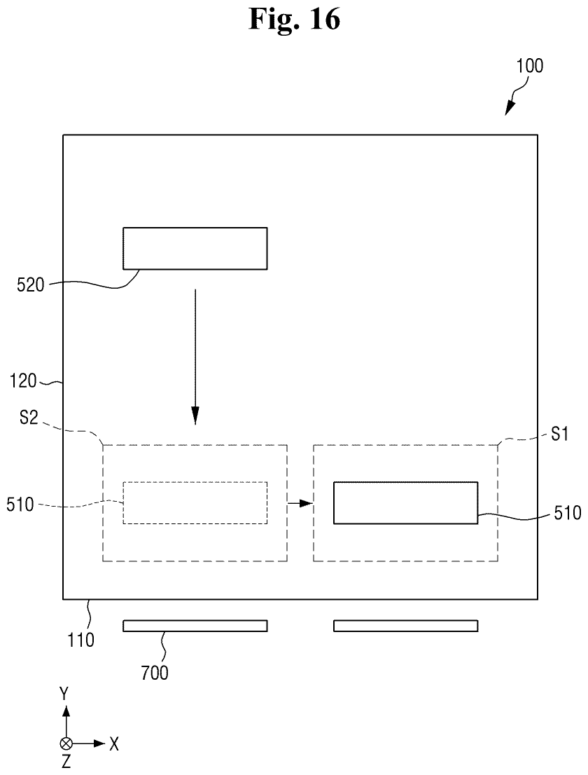

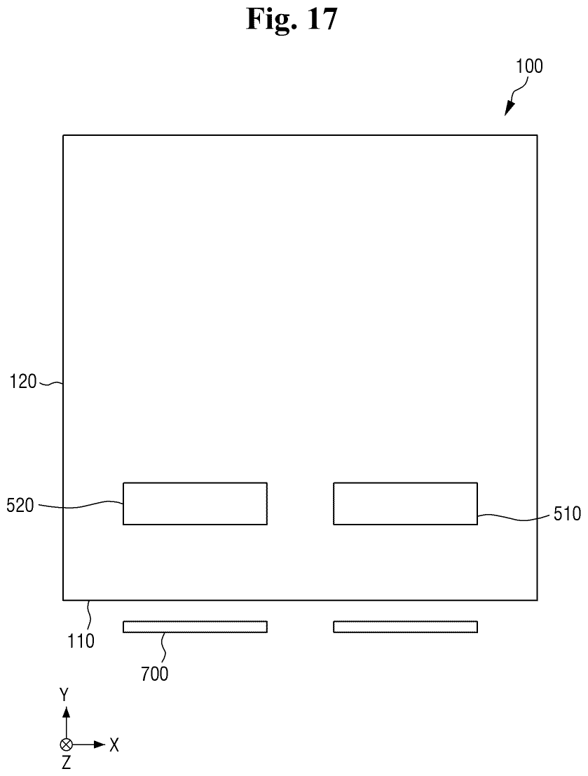

FIGS. 13 to 17 are drawings to illustrate a tower lift control method according to some embodiments of the present disclosure. FIG. 13 is a flow chart illustrating an operation process by which a mast unit 200 including a carrier 300 storing a container 310 may efficiently load and unload a container 310.

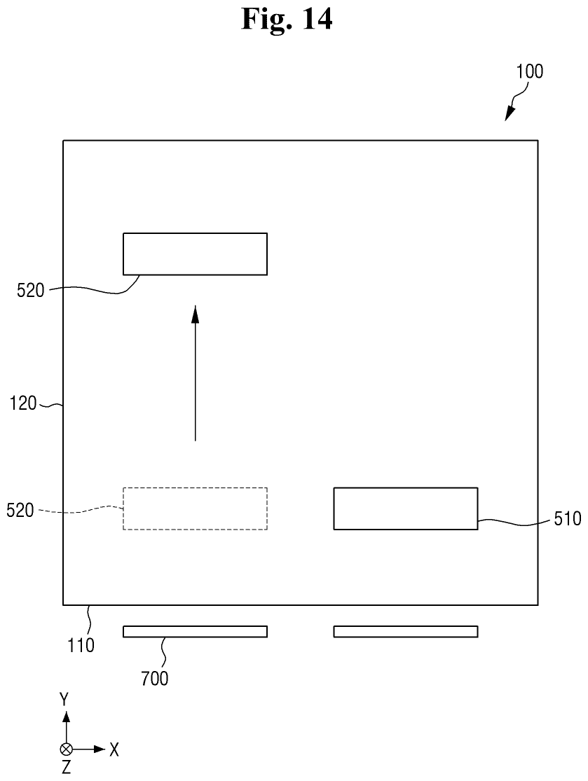

Referring to FIG. 13 and FIG. 14, a first horizontal driving unit 510 coupled with a first mast unit 200 and a second horizontal driving unit 520 coupled with a second mast unit 200 may be disposed on the loading and unloading layer 101. The first horizontal driving unit 510 and the first mast unit 200 may be disposed at a first position S1. The second horizontal driving unit 520 and the second mast unit 200 may be disposed at a second position S2. The second position S2 may be a position at which a container 310 is to be loaded and unloaded. The second position S2 may be spaced apart from the first position S1 in the first direction X. The second mast unit 200 disposed at the second position S2 may be in a state where the loading and unloading is completed.

When the controller 600 transmits an execution notification to the second horizontal driving unit 520 (S11), the second horizontal driving unit 520 moves in the second direction Y (S21). In this case, the second mast unit 200 coupled to the second horizontal driving unit 520 may move together in the second direction Y.

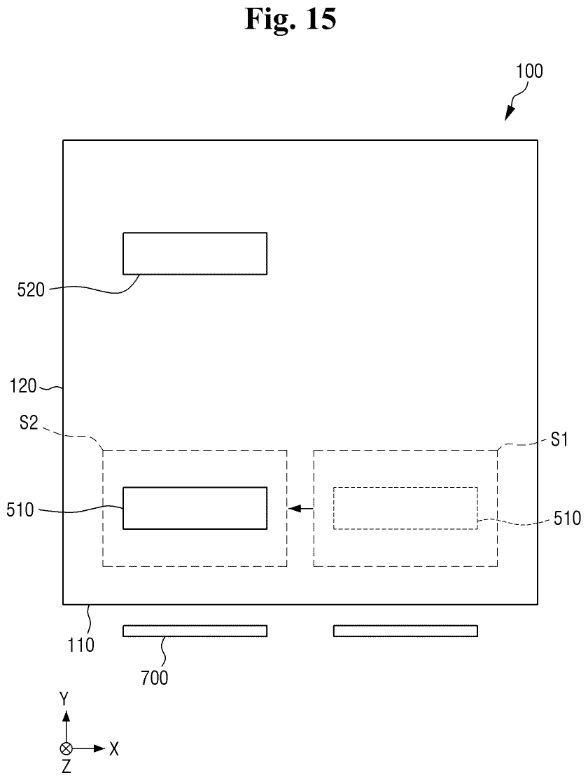

Referring to FIGS. 13 and 15, when the second horizontal driving unit 520 is completed in the second direction Y, it transmits the completion of movement to the first horizontal driving unit 510 (S31). When the first horizontal driving unit 510 receives the completion of movement, it moves from the first position S1 to the second position S2 and loads and unloads the container 310 included in the carrier 300 connected to the first mast unit 200 (S41).

Referring to FIGS. 13, 16, and 17, the first horizontal driving unit 510 then moves to the first position S1 and transmits the completion of movement to the second horizontal driving unit 520 (S51, S61). When the second horizontal driving unit 520 receives the completion of movement, it moves again to the second position S2 (S71).

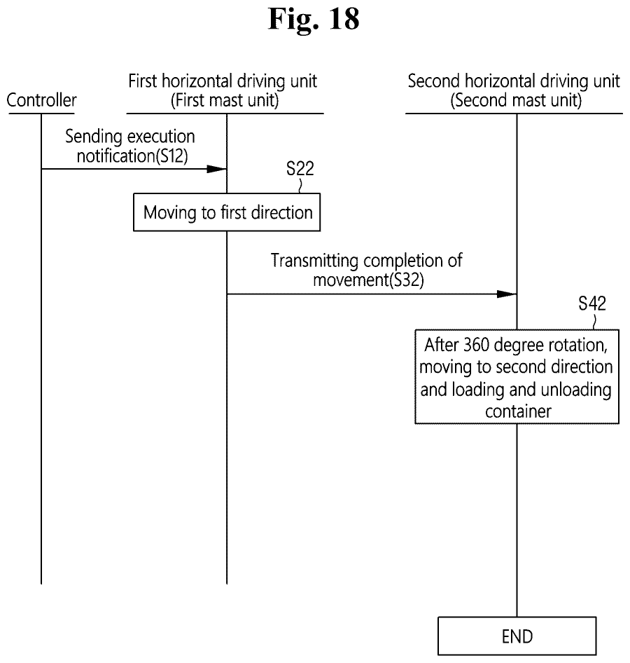

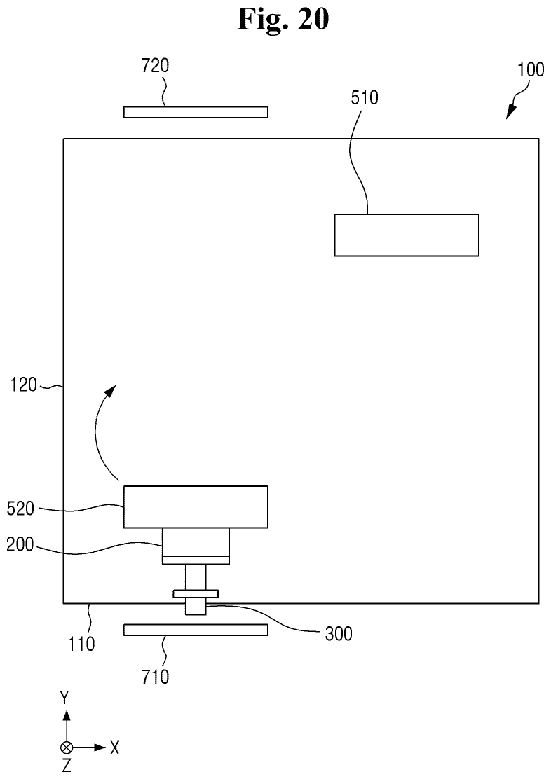

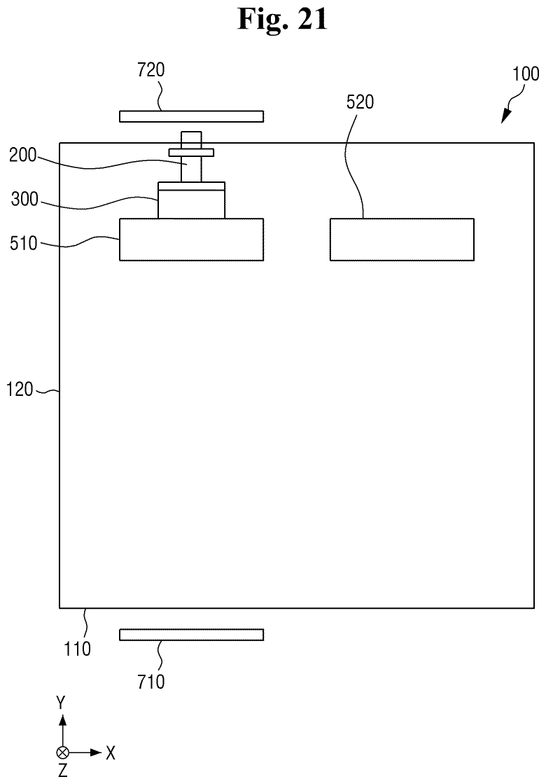

FIGS. 18 to 21 are drawings to illustrate a tower lift control method according to some embodiments of the present disclosure.

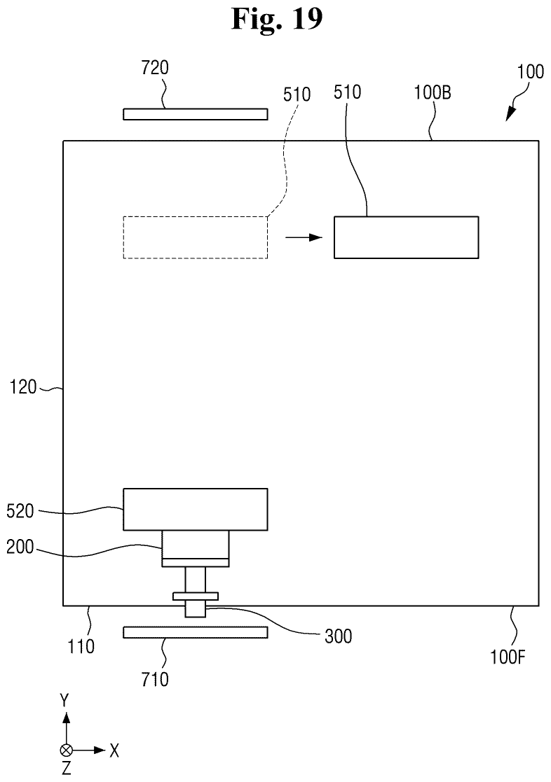

Referring to FIGS. 18 and 19, the first horizontal driving unit 510 coupled with the first mast unit 200 and the second horizontal driving unit 520 coupled with the second mast unit 200 may be disposed on the loading and unloading layer 101. The first horizontal driving unit 510 may be disposed close to the rear loading and unloading port 720 installed spaced apart from the rear 100B of the frame unit 100 in the second direction Y. The second horizontal driving unit 520 may be disposed close to the front loading and unloading port 710 installed spaced apart from the front 100F of the frame unit 100 in the second direction Y. In this case, the first horizontal driving unit 510, the second horizontal driving unit 520, the front loading and unloading port 710, and the rear loading and unloading port 720 may be disposed side by side in the second direction Y.

When the second mast unit 200 attempts to load and unload the container 310 from the rear loading and unloading port 720, the controller 600 transmits an execution notification to the first horizontal driving unit 510 (S12), and the first horizontal driving unit 510 moves in the first direction X (S22), and then transmits the completion of the movement to the second horizontal driving unit 520 (S32).

Referring to FIGS. 18, 20, and 21, the second horizontal driving unit 520 then rotates 360 degrees around the third direction Z as an axis, moves in the second direction Y, and loads and unloads the container 310 from the rear loading and unloading port 720 (S42). In this case, the second horizontal driving unit 520 rotates so that the second mast unit 200 faces the rear loading and unloading port 720.

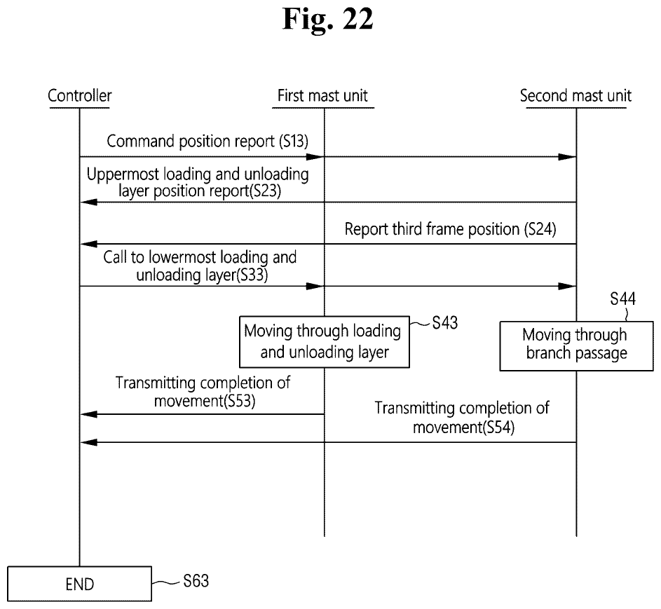

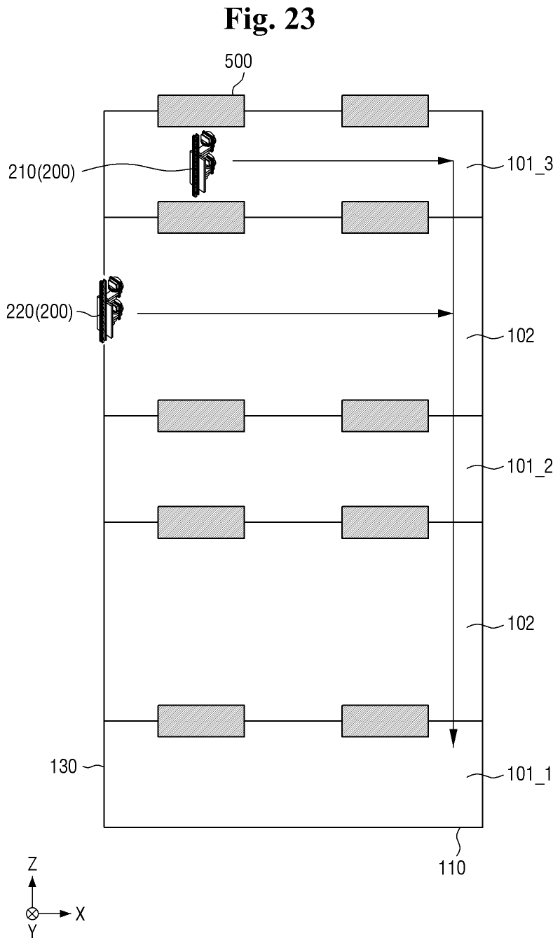

FIGS. 22 and 23 are drawings to illustrate a tower lift control method according to some embodiments of the present disclosure.

Referring to FIGS. 22 and 23, a first mast unit 210 and a second mast unit 220 may be disposed in a frame unit 100. The first mast unit 210 may be disposed in the uppermost loading and unloading layer 101_3. The second mast unit 220 may be disposed in the third frame 130.

The controller 600 commands the first mast unit 210 and the second mast unit 220 to report their positions S13. The first mast unit 210 reports the position of the uppermost loading and unloading layer 101_3 (S23). The second mast unit 220 reports the position of the third frame 130 (S24).

Next, the controller 600 calls the first mast unit 210 and the second mast unit 220 to the lowest loading and unloading layer 101_1 (S33). The first mast unit 210 moves to the lowest loading and unloading layer 101_1 by moving the uppermost loading and unloading layer 101_3 (S43). Since the first mast unit 200 exists in the uppermost loading and unloading layer 101_3 and may not move to the uppermost loading and unloading layer 101_3, the second mast unit 220 moves to the lowest loading and unloading layer 101_1 by moving the branch passage 102 (S44). When the movement is completed, the first mast unit 210 and the second mast unit 220 transmit the completion of the movement to the controller 600 (S53, S54).

The frame unit 100 may include a plurality of loading and unloading layers 101 and a branch passage 102 between the loading and unloading layers 101. When the first mast unit 210 exists in the plurality of loading and unloading layers 101 and the second mast unit 220 may not move through the loading and unloading layers 101, the second mast unit 220 may move through the branch passage 102.

As the semiconductor manufacturing line becomes larger, the single structure of the elevating and lowering movement passage has limitations in the number of carriers, inefficiency due to waiting time, and limitations in the transport speed of materials. Accordingly, a tower lift that may accommodate the high-rise and multi-layer structure due to the enlargement of the semiconductor manufacturing line is required.

However, a tower lift according to some embodiments of the present disclosure may include a frame unit 100 including a first frame 110 extending in a first direction X, a second frame 120 extending in a second direction Y, and a third frame 130 extending in a third direction Z, a horizontal driving unit 500 installed on the first frame 110 and the second frame 120, a vertical driving unit 550 installed on the third frame 130, a mast unit 200 that vertically moves the third frame 130 by the vertical driving unit 550 and horizontally moves along the first frame 110 and the second frame 120 by the horizontal driving unit 500, and a carrier 300 that is fixed to the mast unit 200 and carries a container 310.

The mast unit 200 may be moved integrally with the carrier 300. Since the mast unit 200 may be moved up, down, left, right, and forward and backward, it may efficiently load and unload the container 310 included in the carrier 300. The mast unit 200 may load and unload the container 310 from the loading and unloading port 700 installed apart from the frame unit 100. Since the mast unit 200 may be moved left, right, forward and backward, it may load and unload the container 310 to the loading and unloading port 700 installed close to the front, rear, left and right sides of the frame unit 100.

When a plurality of mast units 200 are operated, a phenomenon in which the mast units 200 are crowded in one loading and unloading layer 101 may occur. Since the frame unit 100 includes a branch passage 102 between the loading and unloading layers 101, the mast unit 200 may optimize its movement path through the branch passage 102. Furthermore, when the paths of the first mast unit 200 and the second mast unit 200 overlap in front of the loading and unloading layer 101, the loading and unloading process may proceed efficiently through an avoidance action of the first mast unit 200 or the second mast unit 200.

Although the embodiments of the present disclosure have been described above with reference to the accompanying drawings, the present disclosure may not be limited to the embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that the embodiments as described above are not restrictive but illustrative in all respects.

What is claimed is:

1. A tower lift comprising:
a frame unit including a first frame extending in a first direction, a second frame extending in a second direction perpendicular to the first direction, and a third frame extending in a third direction perpendicular to the first direction and the second direction;
a horizontal driving unit installed on the first frame and the second frame;
a vertical driving unit installed on the third frame;
a mast unit vertically moving along the third frame by the vertical driving unit and horizontally moving along the first frame and the second frame by the horizontal driving unit; and
a carrier fixed to the mast unit and moving together as the mast unit moves and carrying a container.

2. The tower lift of claim 1, wherein the frame unit includes a plurality of loading and unloading layers including a lowermost loading and unloading layer and an uppermost loading and unloading layer higher than the lowermost loading and unloading layer, and
wherein the mast unit,
moves from the lowermost loading and unloading layer to the uppermost loading and unloading layer along the third frame by the vertical driving unit,
moves horizontally along the first frame by the horizontal driving unit from the uppermost loading and unloading layer, and
moves from the uppermost loading and unloading layer to the lowermost loading and unloading layer along the third frame by the vertical driving unit and circulates clockwise.

3. The tower lift of claim 2, wherein the frame unit further includes a branch passage between the plurality of loading and unloading layers,
wherein a first mast unit among the mast units moves along the plurality of loading and unloading layers and a second mast unit moves along the branch passage.

4. The tower lift of claim 2, wherein the mast unit includes a first mast unit disposed at a first position for loading and unloading the container, and a second mast unit disposed at a second position spaced apart from the first position in a first direction,
when the second mast unit attempts to load and unload at the first position,
the first mast unit moves in the second direction,
the second mast unit moves from the second position to the first position in the first direction, loads and unloads the container, and moves back to the second position,
wherein the first mast unit moves in the second direction and moves back to the first position.

5. The tower lift of claim 4, wherein the horizontal driving unit includes
a first horizontal driving unit corresponding to the first mast unit, and
a second horizontal driving unit corresponding to the second mast unit,
wherein the first horizontal driving unit and the second horizontal driving unit move the first mast unit and the second mast unit in the first direction and the second direction, respectively.

6. The tower lift of claim 1, wherein the vertical driving unit moves the mast unit in a magnetic levitation manner.

7. The tower lift of claim 1, wherein the frame unit includes a plurality of loading and unloading layers including a lowermost loading and unloading layer and an uppermost loading and unloading layer higher than the lowermost loading and unloading layer, and
wherein the mast unit,
moves from the lowermost transfer layer to the uppermost transfer layer along the third frame by the vertical drive unit,
moves horizontally from the uppermost loading and unloading layer to the second frame by the horizontal driving unit, and
moves from the uppermost loading and unloading layer to the lowermost loading and unloading layer along the third frame by the vertical driving unit and circulates clockwise.

8. The tower lift of claim 7, wherein the mast unit loads and unloads the container from a front loading and unloading port installed spaced apart from the front of the frame unit in the second direction,
wherein the horizontal driving unit rotates the mast unit about the third direction and then moves the mast unit in the second direction,
wherein the mast unit loads and unloads the container from a rear loading and unloading port installed spaced apart from the rear of the frame unit in the second direction.

9. The tower lift of claim 8, wherein the mast unit includes a first mast unit disposed in front of the front loading and unloading port and a second mast unit disposed in front of the rear loading and unloading port, and the first mast unit and the second mast unit overlap in the second direction, and
when the first mast unit attempts to load and unload the container from the rear loading and unloading port,
wherein the second mast unit moves in the first direction,
wherein the first mast unit moves in the second direction to move in front of the rear loading and unloading port, loads and unloads the container, and then moves again in front of the front loading and unloading port.

10. The tower lift of claim 1, further comprising a controller for controlling the mast unit and the horizontal driving unit,
wherein the frame unit includes a first loading and unloading layer, a second loading and unloading layer higher than the first loading and unloading layer, and a branch passage disposed between the first loading and unloading layer and the second loading and unloading layer,
wherein the mast unit includes a first mast unit and a second mast unit,
wherein the controller controls,
when the first mast unit is present in the first and second loading and unloading layers and the second mast unit may not move to the first and second loading and unloading layers,
the second mast unit to move to the branch passage using the horizontal driving unit.

11. The tower lift of claim 10, wherein a direction of movement of the mast unit on the first loading and unloading floor and the branch passage is opposite to the direction of movement on the second loading and unloading floor when the first loading and unloading layer is the lowest loading and unloading layer and the second loading and unloading layer is the highest loading and unloading layer.

12. The tower lift of claim 10, wherein a direction in which the mast unit moves in the second loading and unloading layer and the branch passage is the opposite direction to the direction in which it moves in the first loading and unloading layer when the first loading and unloading layer is the lowest loading and unloading layer and the second loading and unloading layer is the highest loading and unloading layer.

13. A control method of tower lift comprising:
a frame unit including a first frame extending in a first direction, a second frame extending in a second direction perpendicular to the first direction, and a third frame extending in a third direction perpendicular to the first direction and the second direction;
a horizontal driving unit installed on the first frame and the second frame;
a vertical driving unit installed on the third frame;
a mast unit moving along the frame unit,
a tower lift is provided, which includes a carrier that is fixed to the mast unit and moves together with the mast unit as it moves, and a controller that controls the mast unit and the horizontal driving unit, and
wherein the vertical driving unit vertically moves the mast unit in a magnetically levitated manner,
wherein the controller controls,
the mast unit to horizontally move the first frame and the second frame by the horizontal driving unit, and
the mast unit to vertically move the third frame by the vertical driving unit.

14. The method of claim 13, wherein the frame unit includes a plurality of loading and unloading layers and a branch passage existing between the plurality of loading and unloading layers,
wherein the controller controls,
the first mast unit among the mast units to move along the loading and unloading layer and the second mast unit to move along the branch passage.

15. The method of claim 13, wherein the frame unit includes a lowermost loading and unloading layer and an uppermost loading and unloading layer higher than the lowermost loading and unloading layer,
wherein the controller controls,
the mast unit to move from the lowermost loading and unloading layer to the uppermost loading and unloading layer along the third frame by the vertical driving unit,
to move horizontally along the first frame or the second frame in the uppermost loading and unloading layer by the horizontal driving unit, and
to move from the uppermost loading and unloading layer to the lowermost loading and unloading layer along the third frame by the vertical driving unit to circulate in a clockwise direction.

16. The method of claim 13, wherein the mast unit includes a first mast unit disposed at a first position for loading and unloading the container, and a second mast unit disposed at a second position spaced apart from the first position in the first direction,
wherein the controller,
moves the first mast unit, which has completed loading and unloading, in the second direction,
horizontally moves the second mast unit from the second position to the first position by the horizontal driving unit, and re-move the second mast unit to the first position after loading and unloading the container, and
controls the first mast unit to move in the second direction to re-move to the first position.

17. The method of claim 13, the controller controls,
the mast unit to load and unload the container from the front loading and unloading port installed spaced apart from the front of the frame unit in the second direction,
the horizontal driving unit to rotate the mast unit about the third direction and then to move the mast unit in the second direction, and
the mast unit to load and unload the container from the rear loading and unloading port installed spaced apart from the rear of the frame unit in the second direction.

18. The method of claim 17, wherein the mast unit includes a first mast unit disposed in front of the front loading and unloading port and a second mast unit disposed in front of the rear loading and unloading port,
wherein the controller controls,
the second mast unit to move in the first direction, and
the first mast unit to move in the second direction to move in front of the rear loading and unloading port, and then to load and unload the container, and then to move again in front of the front loading and unloading port.

19. A tower lift comprising:
a frame unit including a first frame extending in a first direction, a second frame extending in a second direction perpendicular to the first direction, and a third frame extending in a third direction perpendicular to the first direction and the second direction, the frame unit including a front side and a rear side spaced apart in a direction opposite to the front side;
a horizontal driving unit installed on the first frame and the second frame;
a vertical driving unit installed on the third frame;
a mast unit that moves vertically along the third frame in a magnetically levitated manner by the vertical driving unit and moves horizontally along the first frame and the second frame by the horizontal driving unit; and
a carrier that is fixed to the mast unit and moves together with the mast unit as it moves, and carries a container,
wherein the frame unit includes a plurality of loading and unloading layers including a lowermost loading and unloading layer and an uppermost loading and unloading layer higher than the lowermost loading and unloading layer,
wherein the vertical driving unit,
vertically moves the mast unit from the lowermost loading and unloading layer to the uppermost loading and unloading layer at the front of the frame unit, and
vertically moves the mast unit from the uppermost loading and unloading layer to the lowermost loading and unloading layer at the rear of the frame unit.

20. The method of claim 19, wherein the frame unit further includes a branch passage between the plurality of loading and unloading layers,
wherein the first mast unit among the mast units moves along the loading and unloading layers, and the second mast unit moves along the branch passage.
